(19) United States
(12) Patent Application Publication
(10) Pub. No.: US 2017/0067153 A1
(43) Pub. Date: Mar. 9, 2017

(54) SEMICONDUCTOR MANUFACTURING SYSTEM AND METHOD OF OPERATING THE SAME

(71) Applicant: KABUSHIKI KAISHA TOSHIBA, Minato-ku (JP)

(72) Inventor: Kazuhiro MATSUO, Kuwana (JP)

(73) Assignee: KABUSHIKI KAISHA TOSHIBA, Minato-ku (JP)

(21) Appl. No.: 15/016,730

(22) Filed: Feb. 5, 2016

(30) Foreign Application Priority Data
Sep. 7, 2015 (JP) 2015-175654

(51) Int. Cl. C23C 16/44; B08B 5/02; C23C 16/455; H01L 21/67; H01L 21/66

(52) U.S. Cl. CPC C23C 16/4405; H01L 21/67253; H01L 22/12; H01L 22/14; C23C 16/45544; C23C 16/4404; C23C 16/4412; B08B 5/02

(57) ABSTRACT

In one embodiment, a semiconductor manufacturing system includes a processing apparatus configured to process a wafer, an exhaust pump configured to discharge an exhaust gas from the processing apparatus, and a measurement module configured to measure a value that indicates operation of the exhaust pump. The system further includes a controller configured to feed a first gas for pushing out a fragment of a product that is generated by the exhaust gas and is attached to or flows into the exhaust pump, a second gas for cooling the exhaust pump, a third gas for changing characteristics of the product attached to the exhaust pump, or a fourth gas to react with the product attached to the exhaust pump, into the exhaust pump based on the value measured by the measurement module.

### CROSS REFERENCE TO RELATED APPLICATION

This application is based upon and claims the benefit of priority from the prior Japanese Patent Application No. 2015-175654, filed on Sep. 7, 2015, the entire contents of which are incorporated herein by reference.

### FIELD

Embodiments described herein relate to a semiconductor manufacturing system and a method of operating the same.

### BACKGROUND

When an atomic layer deposition (ALD) apparatus forms a film on a wafer, an exhaust gas of the ALD apparatus is discharged by an exhaust pump. However, when the exhaust pump is stopped and is to be restarted, the exhaust pump cannot be restarted in some cases due to a by-product that is generated by the exhaust gas and is attached to a casing or a blade of the exhaust pump. The reason is that the by-product attached to the casing and the by-product attached to the blade may come into contact and be fixed to each other due to expansion of the by-product or contraction of the casing or the blade. A similar problem may occur when the exhaust pump discharges an exhaust gas of an apparatus other than the ALD apparatus that processes the wafer.

### BRIEF DESCRIPTION OF THE DRAWINGS

FIG. 1 is a schematic diagram showing a configuration of a semiconductor manufacturing system of a first embodiment;

FIGS. 2A and 2B are cross-sectional views for describing a problem of an exhaust pump of the first embodiment;

FIGS. 3A and 3B are cross-sectional views for describing another problem of the exhaust pump of the first embodiment;

FIGS. 4A and 4B are cross-sectional views for describing a method of operating the exhaust pump of the first embodiment;

FIG. 5 is a graph for describing the method of operating the exhaust pump of the first embodiment;

FIG. 6 is a schematic diagram showing a configuration of a semiconductor manufacturing system of a second embodiment; and

FIG. 7 is a cross-sectional view for describing a method of operating an exhaust pump of the second embodiment.

### DETAILED DESCRIPTION

Embodiments will now be explained with reference to the accompanying drawings.

In one embodiment, a semiconductor manufacturing system includes a processing apparatus configured to process a wafer, an exhaust pump configured to discharge an exhaust gas from the processing apparatus, and a measurement module configured to measure a value that indicates operation of the exhaust pump. The system further includes a controller configured to feed a first gas for pushing out a fragment of a product that is generated by the exhaust gas and is attached to or flows into the exhaust pump, a second gas for cooling the exhaust pump, a third gas for changing characteristics of the product attached to the exhaust pump, or a fourth gas to react with the product attached to the exhaust pump, into the exhaust pump based on the value measured by the measurement module.

### First Embodiment

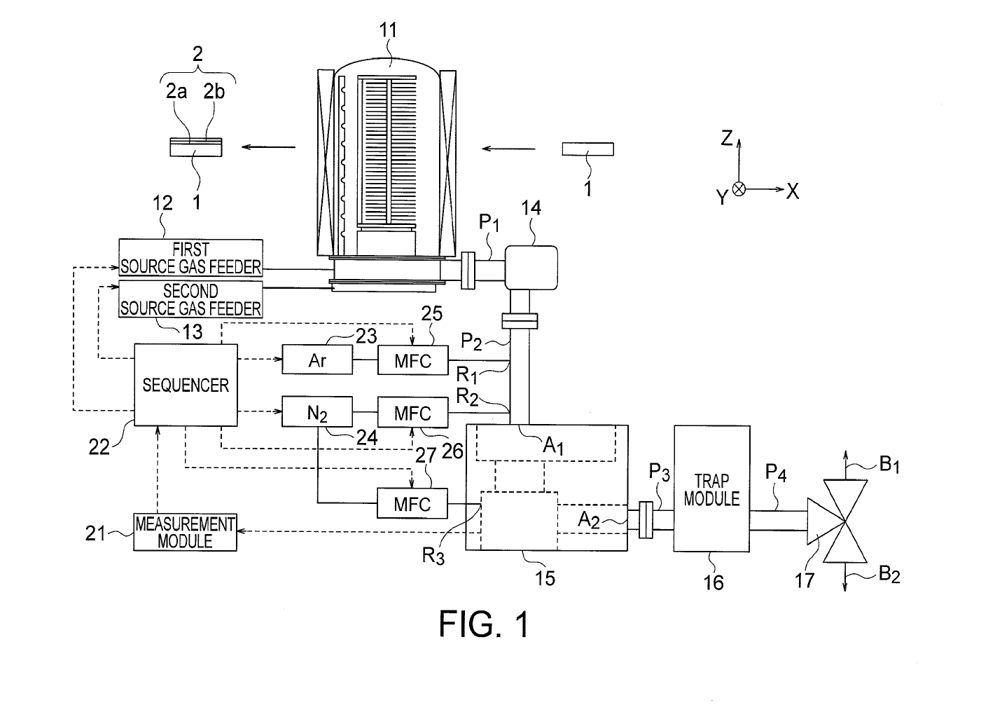

FIG. 1 is a schematic diagram showing a configuration of a semiconductor manufacturing system of a first embodiment.

The semiconductor manufacturing system of FIG. 1 includes an ALD reactor 11 of an ALD apparatus as an example of a processing apparatus, a first source gas feeder 12, a second source gas feeder 13, a pressure adjustment valve 14, an exhaust pump 15, a trap module 16, a switching valve 17, a measurement module 21, a sequencer 22 as an example of a controller, an argon gas feeder 23, a nitrogen gas feeder 24, and mass flow controllers (MFCs) 25, 26 and 27.

The ALD reactor 11 repeatedly deposits plural layers 2a and 2b on a surface of a wafer 1 by ALD. As a result, a film 2 including these layers 2a and 2b is formed on the wafer 1. Examples of the wafer 1 include a semiconductor substrate, and a workpiece substrate that includes a semiconductor substrate and a workpiece layer. Examples of the film 2 include an oxide film and a nitride film. FIG. 1 schematically illustrates import of the wafer 1 into the ALD reactor 11, and export of the wafer 1 from the ALD reactor 11 after forming the film 2. The ALD reactor 11 can house plural wafers 1.

FIG. 1 shows an X direction and a Y direction parallel to the surface of the wafer 1 and perpendicular to each other, and a Z direction perpendicular to the surface of the wafer 1. In the present specification, a +Z direction is handled as an upward direction, and a −Z direction is handled as a downward direction. For example, as for the positional relationship between the wafer 1 and the film 2, it is expressed that the wafer 1 is below the film 2. The −Z direction may coincide with a gravity direction or may not coincide with the gravity direction.

The first source gas feeder 12 feeds a first source gas to the ALD reactor 11. The second source gas feeder 13 feeds a second source gas to the ALD reactor 11. An example of the first source gas is a precursor to be adsorbed to the surface of the wafer 1. An example of the second source gas is an oxidant to react with the precursor to form the film 2. The semiconductor manufacturing system of the present embodiment may include only one source gas feeder or may include three or more source gas feeders.

The pressure adjustment valve 14 is connected to the ALD reactor 11 through a pipe P₁ and is used for controlling circulation and flow rate of the exhaust gas from the ALD reactor 11. The semiconductor manufacturing system of the present embodiment can adjust the opening of the pressure adjustment valve 14 to control the pressure in the ALD reactor 11.

The exhaust pump 15 is connected to the pressure adjustment valve 14 through a pipe P₂ and operates to discharge the exhaust gas from the ALD reactor 11. The exhaust pump 15 includes an inlet A₁ of the exhaust gas connected to the pipe P₂ and an outlet A₂ of the exhaust gas connected to a pipe P₃.

The trap module 16 is connected to the exhaust pump 15 through the pipe P₃ and removes a predetermined substance from the exhaust gas from the ALD reactor 11. An example of the predetermined substance is a by-product generated by the exhaust gas.

The switching valve 17 is connected to the trap module 16 through a pipe P₄ and switches a flow path for guiding the exhaust gas from the ALD reactor 11. Reference sign B₁ shows that the exhaust gas is guided to a flow path for exhaust, and reference sign B₂ shows that the exhaust gas is guided to a flow path for detoxification.

The measurement module 21 measures a value that indicates the operation of the exhaust pump 15. For example, the measurement module 21 measures the value that indicates a rotation, current, sound, vibration or temperature of the exhaust pump 15. Examples of the value include the number of rotations of the exhaust pump 15, a current value in the exhaust pump 15, a decibel value of the sound near the exhaust pump 15, the number of vibrations of the exhaust pump 15, and the temperature in the exhaust pump 15.

The sequencer 22 controls various kinds of operation of the semiconductor manufacturing system. For example, the sequencer 22 controls the operation of the argon gas feeder 23, the nitrogen gas feeder 24 and the MFCs 25, 26, and 27 based on the value measured by the measurement module 21. Details of the control by the sequencer 22 will be described later.

The argon gas feeder 23 feeds an argon (Ar) gas to a feeding port R₁ through the MFC 25. The feeding port R₁ is provided in the pipe P₂. The argon gas is fed from the argon gas feeder 23 into the exhaust pump 15 through the feeding port R₁. The MFC 25 is used for adjusting the mass flow rate of the argon gas fed to the feeding port R₁. The argon gas is used for cooling the exhaust pump 15. The argon gas is an example of a second gas.

The nitrogen gas feeder 24 feeds a nitrogen (N₂) gas to feeding ports R₂ and R₃ through the MFCs 26 and 27. The feeding port R₂ is provided in the pipe P₂. The feeding port R₃ is provided between the inlet A₁ and the outlet A₂ of the exhaust pump 15. The nitrogen gas is fed from the nitrogen gas feeder 24 into the exhaust pump 15 through one or both of the feeding ports R₂ and R₃. The MFC 26 is used for adjusting the mass flow rate of the nitrogen gas fed to the feeding port R₂. The MFC 27 is used for adjusting the mass flow rate of the nitrogen gas fed to the feeding port R₃. The nitrogen gas is used for pushing out a fragment of the by-product or the like in the exhaust pump 15 to prevent the fragment of the by-product from being caught in a driving module (for example, rotor) of the exhaust pump 15. The nitrogen gas is an example of a first gas.

The argon gas feeder 23 and the nitrogen gas feeder 24 are examples of one or more gas feeders. The MFCs 25, 26 and 27 are examples of one or more flow rate adjustment modules. The semiconductor manufacturing system of the present embodiment may separately include a nitrogen gas feeder for the MFC 26 and a nitrogen gas feeder for the MFC 27.

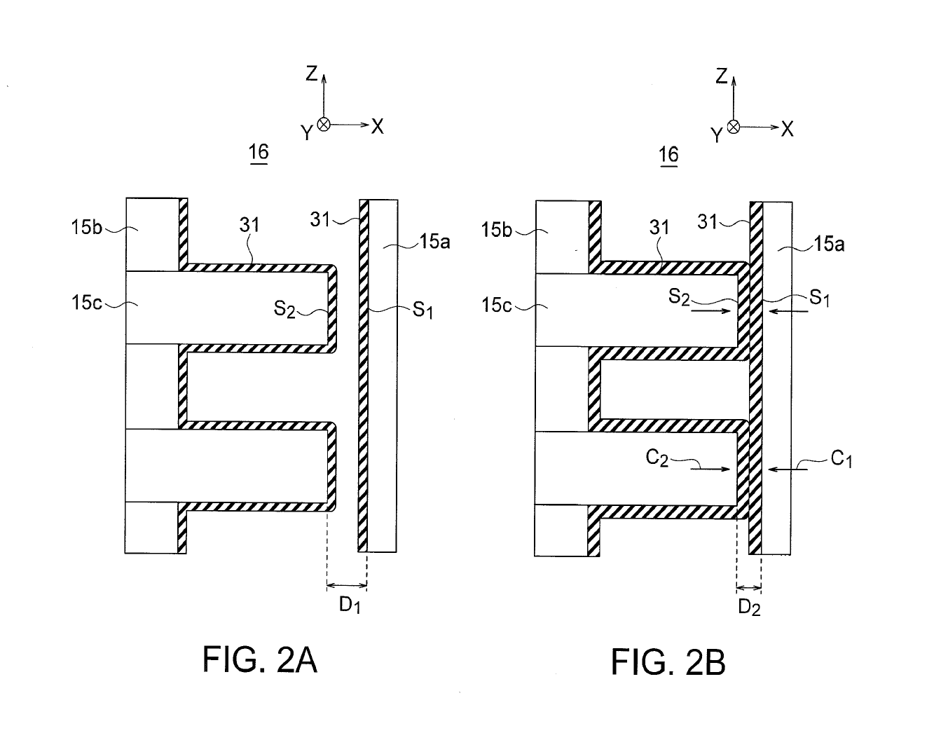

FIGS. 2A and 2B are cross-sectional views for describing a problem of the exhaust pump 15 of the first embodiment.

As shown in FIG. 2A, the exhaust pump 15 includes a casing 15a, a rotor 15b provided in the casing 15a, and blades 15c attached to the rotor 15b. The rotor 15b rotates with the blades 15c in the casing 15a. The rotation of the blades 15c allows the exhaust pump 15 to discharge the exhaust gas from the ALD reactor 11. The casing 15a is an example of a first portion. The rotor 15b and the blades 15c are examples of a second portion.

FIG. 2A shows the exhaust pump 15 in operation. The rotor 15b is rotating in FIG. 2A. Reference sign S₁ denotes an inner face of the casing 15a. Reference sign S₂ denotes an outer face of each blade 15c opposing the inner face S₁ of the casing 15a. Reference sign D₁ denotes a distance between the inner face S₁ of the casing 15a and the outer face S₂ of each blade 15c.

FIG. 2A shows a by-product 31 attached to the exhaust pump 15. The by-product 31 is generated by the exhaust gas from the ALD reactor 11 and is attached to the inner face S₁ of the casing 15a, the outer face S₂ of each blade 15c and the like. In some cases, the by-product 31 is generated by the exhaust gas on the upstream of the exhaust pump 15 and flows into the exhaust pump 15. The by-product 31 is, for example, the same substance as the film 2. The by-product 31 is an example of a product of the disclosure.

FIG. 2B shows a suddenly stopping exhaust pump 15. In FIG. 2B, the rotation of the rotor 15b is suddenly stopped. In this case, the temperature of the exhaust pump 15 rapidly drops, and the casing 15a, the rotor 15b, and the blades 15c contract. Therefore, the inner face S₁ and the outer face S₂ come close to each other as indicated by arrows C₁ and C₂, and the distance between the inner face S₁ and the outer face S₂ is reduced. FIG. 2B shows that the distance is changed from D₁ to D₂. If the air flows into the exhaust pump 15 in this state, the by-product 31 expands. The reason of the expansion is that the by-product 31 absorbs moisture in the air or that the by-product 31 is hydrolyzed by the moisture in the air.

When the exhaust pump 15 contracts due to the expansion of the by-product 31, the by-product 31 of the inner face S₁ and the by-product 31 of the outer face S₂ come into contact and fixed to each other. Therefore, the rotor 15b does not rotate, or it is difficult for the rotor 15b to rotate, when the exhaust pump 15 is restarted. As a result, the exhaust pump 15 cannot be restarted.

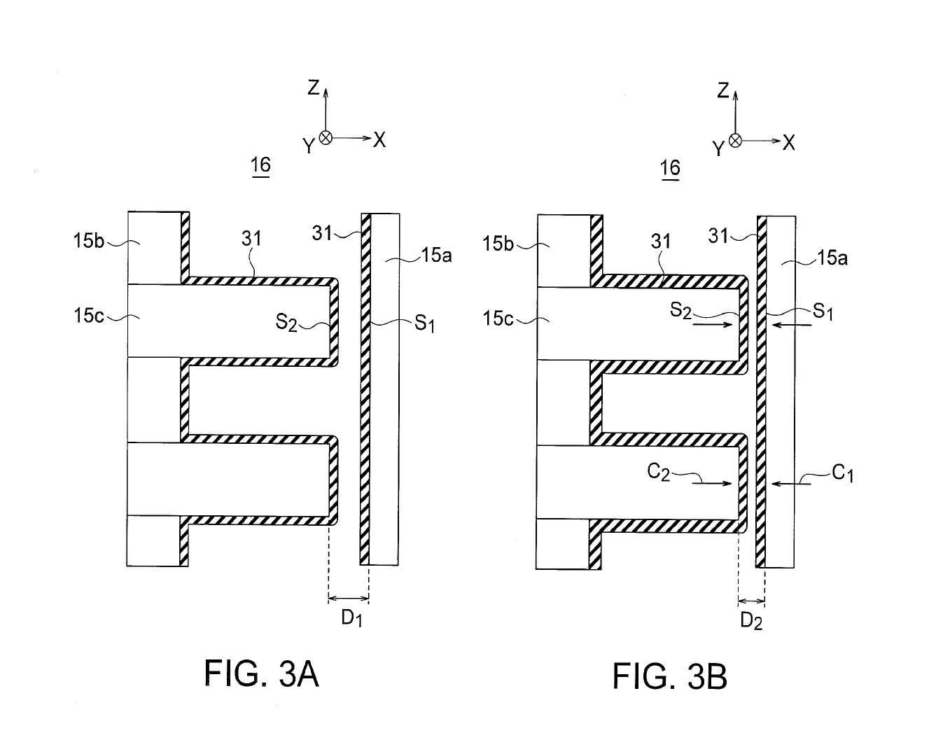

FIGS. 3A and 3B are cross-sectional views for describing another problem of the exhaust pump 15 of the first embodiment.

FIG. 3A shows the exhaust pump 15 in operation. FIG. 3B shows a slowly stopping exhaust pump 15. In this case, the temperature of the by-product 31 and the exhaust pump 15 slowly drops, and part of the by-product 31 of the inner face S₁ and the by-product 31 of the outer face S₂ is scraped off before the rotation of the rotor 15b completely stops. This can prevent the fixation of the by-product 31 of the inner face S₁ and the by-product 31 of the outer face S₂, and the exhaust pump 15 can be restarted.

The exhaust pump 15 is stopped at the maintenance of the semiconductor manufacturing system, for example. In this case, the exhaust pump 15 cannot be restarted if the exhaust pump 15 is suddenly stopped as in FIG. 2B. This problem can be handled by slowly stopping the exhaust pump 15 as in FIG. 3B. However, it takes long time to stop the exhaust pump 15 in the case of FIG. 3B. Furthermore, the possibility of the fixation of the by-product 31 still remains in the case of FIG. 3B, and the exhaust pump 15 in this case cannot be restarted.

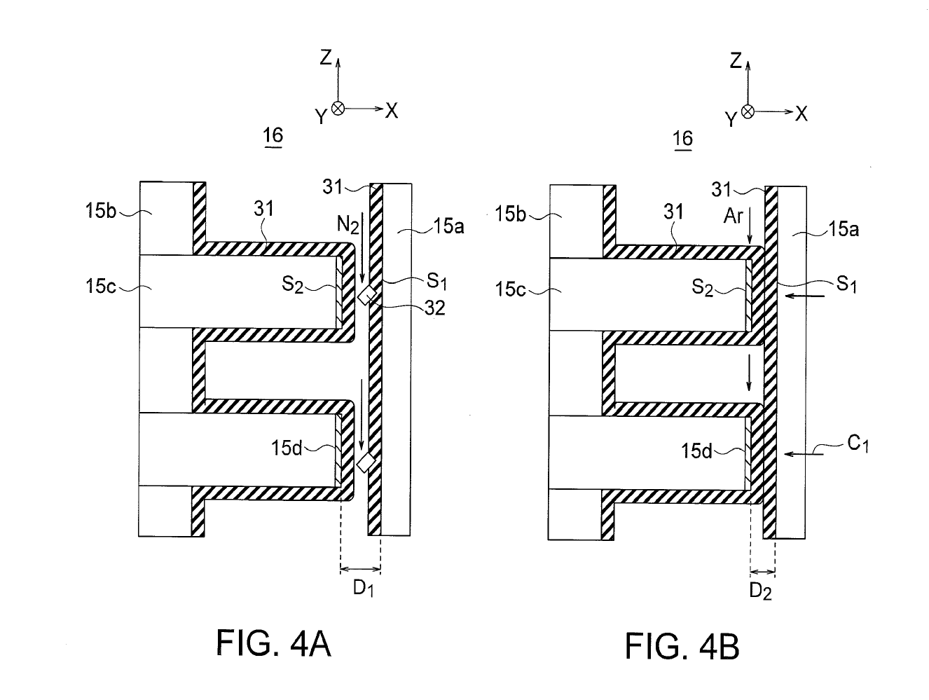

FIGS. 4A and 4B are cross-sectional views for describing a method of operating the exhaust pump 15 of the first embodiment.

FIG. 4A shows the exhaust pump 15 in operation. In FIG. 4A, a nitrogen gas is fed from the nitrogen gas feeder 24 into the exhaust pump 15. FIG. 4A shows a falling object of a fragment 32 of the by-product 31 that is attached to or flows into the exhaust pump 15. In the present embodiment, the nitrogen gas with a large flow rate can be fed into the exhaust pump 15 to push out the fragment 32 to prevent the fragment 32 and the like in the exhaust pump 15 from being caught in the driving module (for example, rotor 15b) of the exhaust pump 15. The fragment 32 is pushed out by the nitrogen gas with the large flow rate to scrape off the by-product 31 of the inner face S₁ and the outer face S₂. In the present embodiment, the nitrogen gas heated by the nitrogen gas feeder 24 may be fed into the exhaust pump 15 to prevent the nitrogen gas from cooling the exhaust pump 15.

According to the present embodiment, the nitrogen gas can be fed into the exhaust pump 15 to prevent the fixation of the by-product 31 of the inner face S₁ and the by-product 31 of the outer face S₂. This can prevent the situation that the exhaust pump 15 cannot be restarted.

FIG. 4B also shows the exhaust pump 15 in operation. In FIG. 4B, an argon gas is fed from the argon gas feeder 25 into the exhaust pump 15. The argon gas is characterized by a low thermal conductivity. Therefore, the argon gas can be fed into the exhaust pump 15 to basically cool only the casing 15a in the present embodiment. The reason is that the rotating rotor 15b generates heat, and the rotor 15b is not cooled much by the argon gas with a low thermal conductivity. As a result, only the casing 15a contracts as indicated by the arrow C₁, and the by-product 31 of the inner face S₁ and the by-product 31 of the outer face S₂ come into contact with each other. In this case, since the rotor 15b is rotating, this contact mutually scrapes off the by-product 31 of the inner face S₁ and the by-product 31 of the outer face S₂.

According to the present embodiment, the argon gas can be fed into the exhaust pump 15 to bring the by-products 31 of the inner face S₁ and the outer face S₂ into contact with each other, and the by-products 31 can be scraped off from the inner face S₁ and the outer face S₂. This can prevent the situation that the exhaust pump 15 cannot be restarted.

It is desirable that the exhaust pump 15 of the present embodiment includes a coating film 15d on the outer face S₂ of the blade 15c. This can prevent damage of the blades 15c by the contact of the by-products 31 of the inner face S₁ and the outer face S₂. Examples of the coating film 15d include a plating layer and a polymer film.

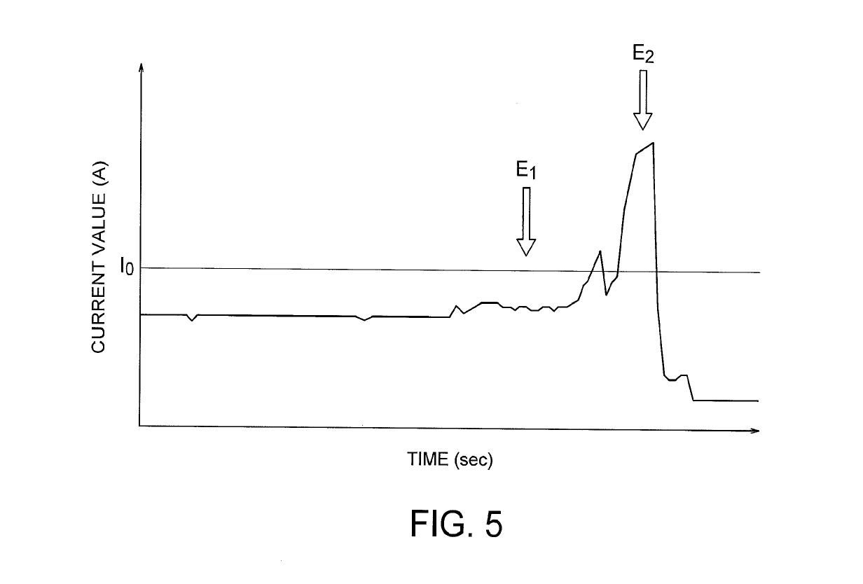

In the present embodiment, the exhaust pump 15 is stopped after the nitrogen gas and the argon gas are fed to the exhaust pump 15 in operation. Therefore, according to the present embodiment, the exhaust pump 15 can be appropriately restarted without slowly stopping the exhaust pump 15. In the present embodiment, the nitrogen gas and the argon gas may be fed into the exhaust pump 15 at the same time or may be separately fed into the exhaust pump 15. The timing and the amount of feeding of the nitrogen gas and the argon gas will be described with reference to FIG. 5.

FIG. 5 is a graph for describing the method of operating the exhaust pump 15 of the first embodiment.

The vertical axis of FIG. 5 indicates a current value measured by the measurement module 21 at a predetermined spot in the exhaust pump 15. The horizontal axis of FIG. 5 indicates time. Reference sign I₀ denotes a threshold of the current value.

When the amount of attachment of the by-product 31 in the exhaust pump 15 is small, the current value is sufficiently lower than the threshold I₀. However, when the amount of attachment of the by-product 31 is large, the current value increases as indicated by an arrow E₁. The reason is that the by-product 31 makes the rotor 15b hard to rotate, and the exhaust pump 15 increases the current value to maintain the number of rotations of the rotor 15b. When the amount of attachment of the by-product 31 is larger, the current value further increases as indicated by an arrow E₂, and the current value is higher than the threshold I₀. In this case, the exhaust pump 15 in operation may be stopped by the by-product 31.

The sequencer 22 of the present embodiment receives a measurement result of the current value from the measurement module 21 and feeds the nitrogen gas and the argon gas into the exhaust pump 15 based on the current value. Specifically, when the current value is lower than the threshold I₀, the sequencer 22 outputs feeding stop signals to the nitrogen gas feeder 24 and the argon gas feeder 23 to stop feeding the nitrogen gas and the argon gas. When the current value is higher than the threshold Iₒ, the sequencer 22 outputs the feeding instruction signals to the nitrogen gas feeder 24 and the argon gas feeder 23 to feed the nitrogen gas and the argon gas into the exhaust pump 15. As a result, the amount of attachment of the by-product 31 can be reduced, and the rotor 15b can be easily rotated again. The nitrogen gas and the argon gas are fed until the current value is lower than the threshold Iₒ, for example.

The sequencer 22 of the present embodiment controls the flow rate of the nitrogen gas and the flow rate of the argon gas based on the current value from the measurement module 21. For example, when the difference between the current value and the threshold Iₒ increases, the sequencer 22 causes the MFC 26 or 27 to increase the flow rate of the nitrogen gas and causes the MFC 25 to increase the flow rate of the argon gas. When the difference between the current value and the threshold I₀ decreases, the sequencer 22 causes the MFC 26 or 27 to decrease the flow rate of the nitrogen gas and causes the MFC 25 to decrease the flow rate of the argon gas. This can more effectively reduce the amount of attachment of the by-product 31.

The feeding of the nitrogen gas and the argon gas may be controlled by different thresholds. Also, the feeding of the nitrogen gas and the argon gas may be controlled by measurement values of different types. For example, the sequencer 22 may feed the nitrogen gas based on the current value in the exhaust pump 15 and may feed the argon gas based on the decibel value of the sound near the exhaust pump 15.

As described above, the measurement module 21 of the present embodiment measures the value that indicates the operation of the exhaust pump 15, and the sequencer 22 of the present embodiment feeds the first gas for pushing out the fragment 32 to scrape off the by-product 31 or the second gas for cooling the exhaust pump 15 into the exhaust pump 15 based on the value measured by the measurement module 21. An example of the first gas is a nitrogen gas, and an example of the second gas is an argon gas. Therefore, according to the present embodiment, the by-product 31 can be appropriately processed during the operation of the exhaust pump 15, and the exhaust pump 15 can be appropriately restarted.

In the present embodiment, a simulant material for simulating the fragment 32 of the by-product 31 may be fed into the exhaust pump 15 in operation in order to scrape off the by-product 31. An example of the simulant material is powder with the same quality as the by-product 31. According to the present embodiment, the simulant material can be used to push out the simulant material by the nitrogen gas with a large flow rate, and the by-product 31 can be scraped off.

An experiment was conducted in which the flow rate of the nitrogen gas was changed in plural levels during the operation of the exhaust pump 15. In the experiment, the frequency that the fragment 32 stopped the exhaust pump 15 in operation was measured. As a result, it is found that the frequency of the stop of the exhaust pump 15 decreases with an increase in the flow rate of the nitrogen gas.

### Second Embodiment

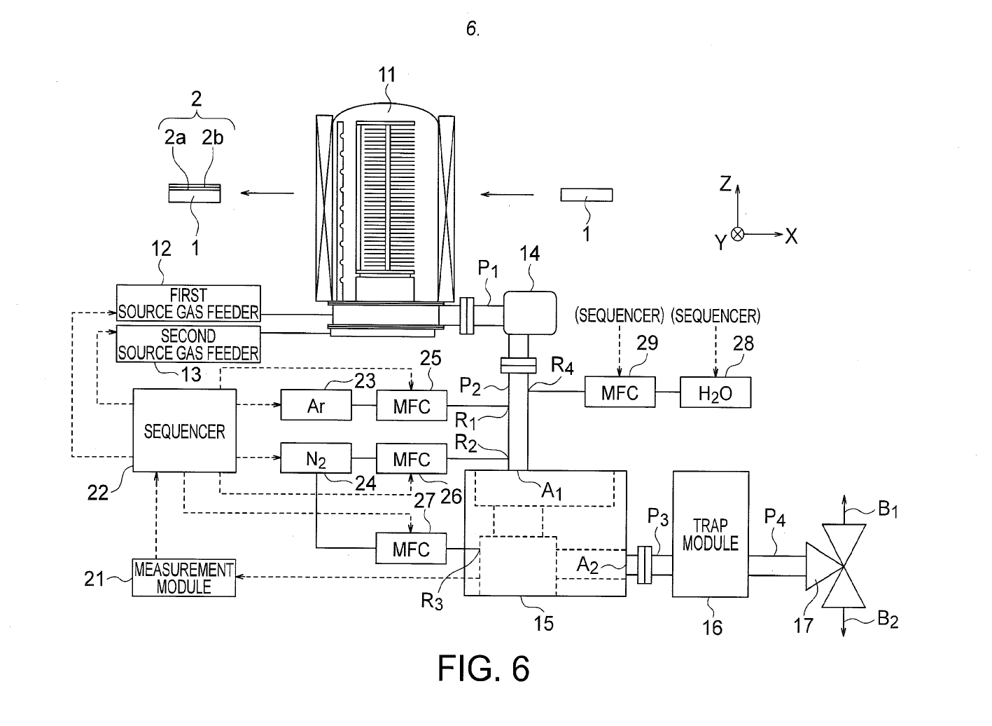

FIG. 6 is a schematic diagram showing a configuration of a semiconductor manufacturing system of a second embodiment.

In addition to the components shown in FIG. 1, the semiconductor manufacturing system of FIG. 6 further includes a moisture feeder 28 and an MFC 29. The moisture feeder 28 is an example of one or more gas feeders. The MFC 29 is an example of one or more flow rate adjustment modules.

The moisture feeder 28 feeds a gas including moisture to a feeding port R₄ through the MFC 29. The feeding port R₄ is provided in the pipe P₂. An example of the gas is air. The air is fed from the moisture feeder 28 into the exhaust pump 15 through the feeding port R₄. The MFC 29 is used for adjusting the mass flow rate of the air fed to the feeding port R₄. The air is used for changing the characteristics of the by-product 31 generated by the exhaust gas and attached to the exhaust pump 15. The air is an example of a third gas.

The moisture feeder 28 may be replaced by a hydrofluoric acid feeder that feeds a hydrofluoric acid (HF) gas. The hydrofluoric acid gas can be used for reaction with the by-product 31. The hydrofluoric acid gas is an example of a fourth gas.

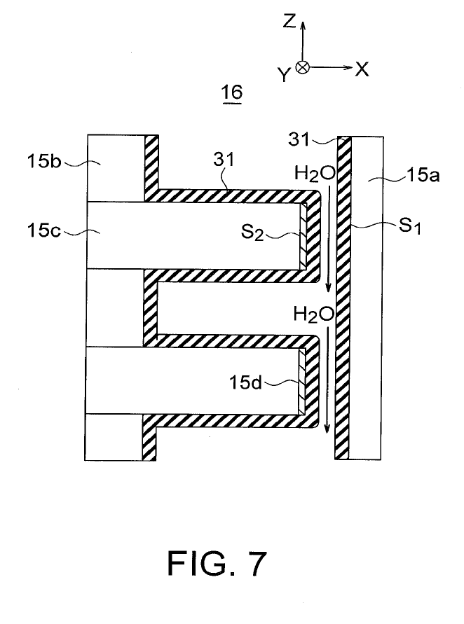

FIG. 7 is a cross-sectional view for describing a method of operating the exhaust pump 15 of the second embodiment.

FIG. 7 shows the exhaust pump 15 in operation. In FIG. 7, the air is fed from the moisture feeder 28 into the exhaust pump 15. In the present embodiment, the air is fed into the exhaust pump 15 to expose the by-product 31 of the inner face S₁ and the outer face S₂ to the moisture. As a result, the characteristics of the by-product 31 are changed by the absorption of the moisture by the by-product 31 and the hydrolysis of the by-product 31 by the moisture. Specifically, the quality of the by-product 31 is degraded, and the by-product 31 becomes brittle and can be easily scraped off.

Therefore, according to the present embodiment, the air can be fed into the exhaust pump 15 to easily scrape off the by-product 31 from the inner face S₁ and the outer face S₂. This can prevent the situation that the exhaust pump 15 cannot be restarted.

Meanwhile, the exposure of the by-product 31 of the inner face S₁ and the outer face S₂ to the hydrofluoric acid gas degrades the quality of the by-product 31, and the by-product 31 can be easily removed from the inner face S₁ and the outer face S₂. The reason is that the hydrofluoric acid gas can be easily reacted with many by-products 31, as is apparent from the frequent use in etching. An etching gas other than the hydrofluoric acid gas may be used in the present embodiment.

The timing and amount of feeding of the air and the hydrofluoric acid gas can be controlled in the same way as the timing and amount of feeding of the nitrogen gas and the argon gas. The sequencer 22 of the present embodiment receives a measurement result of the current value from the measurement module 21 and feeds the air (or hydrofluoric acid gas) into the exhaust pump 15 based on the current value. The sequencer 22 controls the feeding and stopping of the air through the moisture feeder 28 and controls the flow rate of the air through the MFC 29.

The feeding of the nitrogen gas, the argon gas and the air may be controlled by different thresholds. Also, the feeding of the nitrogen gas, the argon gas, and the air may be controlled by measurement values of different types. For example, the sequencer 22 may feed the nitrogen gas based on the current value in the exhaust pump 15, feed the argon gas based on the decibel value of the sound near the exhaust pump 15, and feed the air based on the temperature in the exhaust pump 15.

As described above, the sequencer 22 of the present embodiment feeds the first gas for pushing out the fragment 32 of the by-product 31, the second gas for cooling the exhaust pump 15, the third gas for changing the characteristics of the by-product 31, and the fourth gas to react with the by-product 31, into the exhaust pump 15 based on the value measured by the measurement module 21. An example of the first gas is a nitrogen gas, and an example of the second gas is an argon gas. An example of the third gas is air, and an example of the fourth gas is a hydrofluoric acid gas. Therefore, according to the present embodiment, the by-product 31 can be appropriately processed during the operation of the exhaust pump 15, and the exhaust pump 15 can be appropriately restarted.

The ALD reactor 11 of the first and second embodiments may be replaced by another apparatus that processes the wafer 1. Examples of this apparatus include a furnace that heats the wafer 1 and a chamber that processes the film 2 on the wafer 1. The exhaust pump 15 of the first and second embodiments can also be applied to the exhaust gas of this apparatus.

While certain embodiments have been described, these embodiments have been presented by way of example only, and are not intended to limit the scope of the inventions. Indeed, the novel systems and methods described herein may be embodied in a variety of other forms; furthermore, various omissions, substitutions and changes in the form of the systems and methods described herein may be made without departing from the spirit of the inventions. The accompanying claims and their equivalents are intended to cover such forms or modifications as would fall within the scope and spirit of the inventions.

1. A semiconductor manufacturing system comprising:
a processing apparatus configured to process a wafer;
an exhaust pump configured to discharge an exhaust gas from the processing apparatus;
a measurement module configured to measure a value that indicates operation of the exhaust pump; and
a controller configured to feed a first gas for pushing out a fragment of a product that is generated by the exhaust gas and is attached to or flows into the exhaust pump, a second gas for cooling the exhaust pump, a third gas for changing characteristics of the product attached to the exhaust pump, or a fourth gas to react with the product attached to the exhaust pump, into the exhaust pump based on the value measured by the measurement module.

2. The system of claim 1, wherein the exhaust pump comprises a first portion, and a second portion rotating in the first portion and having an outer face that opposes an inner face of the first portion.

3. The system of claim 2, wherein the first gas causes the fragment to scrape off the product attached to the inner face of the first portion or the outer face of the second portion.

4. The system of claim 2, wherein the second gas cools the exhaust pump to bring the product attached to the inner face of the first portion and the product attached to the outer face of the second portion into contact with each other.

5. The system of claim 2, wherein the third gas changes the characteristics of the product attached to the inner face of the first portion or the outer face of the second portion.

6. The system of claim 2, wherein the fourth gas reacts with the product attached to the inner face of the first portion or the outer face of the second portion.

7. The system of claim 1, wherein the first gas is a nitrogen gas.

8. The system of claim 1, wherein the second gas is an argon gas.

9. The system of claim 1, wherein the third gas is a gas including moisture.

10. The system of claim 1, wherein the fourth gas is a hydrofluoric acid gas.

11. The system of claim 2, wherein the exhaust pump further comprises a coating film provided on the outer face of the second portion.

12. The system of claim 1, wherein the controller feeds the first, second, third or fourth gas into the exhaust pump during the operation of the exhaust pump.

13. The system of claim 1, wherein the measurement module measures the value that indicates a rotation, current, sound, vibration or temperature of the exhaust pump.

14. The system of claim 1, wherein the first, second, third or fourth gas is fed to a feeding port provided on a flow path between the processing apparatus and the exhaust pump, or to a feeding port provided between an inlet and an outlet of the exhaust pump.

15. The system of claim 1, further comprising:
one or more gas feeders configured to feed the first, second, third or fourth gas; and
one or more flow rate adjustment modules configured to adjust a flow rate of the first, second, third or fourth gas.

16. A method of operating a semiconductor manufacturing system, comprising:
processing a wafer by a processing apparatus;
discharging an exhaust gas from the processing apparatus by an exhaust pump;
measuring, by a measurement module, a value that indicates operation of the exhaust pump; and
feeding a first gas for pushing out a fragment of a product that is generated by the exhaust gas and is attached to or flows into the exhaust pump, a second gas for cooling the exhaust pump, a third gas for changing characteristics of the product attached to the exhaust pump, or a fourth gas to react with the product attached to the exhaust pump, into the exhaust pump based on the value measured by the measurement module.

17. The method of claim 16, wherein the exhaust pump comprises a first portion, and a second portion rotating in the first portion and having an outer face that opposes an inner face of the first portion.

18. The method of claim 16, wherein the first, second, third or fourth gas is fed into the exhaust pump during the operation of the exhaust pump.

19. The method of claim 16, wherein the measurement module measures the value that indicates a rotation, current, sound, vibration or temperature of the exhaust pump.

20. The method of claim 16, further comprising feeding a simulant material for simulating the product into the exhaust pump.
